(19) United States
(12) Patent Application Publication
(10) Pub. No.: US 2020/0284474 A1
(43) Pub. Date: Sep. 10, 2020

(54) PROTECTIVE AMORPHOUS COATING FOR SOLAR THERMAL APPLICATIONS AND METHOD OF MAKING SAME

(71) Applicant: RIOGLASS SOLAR SCH, SL, Aznalcollar - Sevilla (ES)

(72) Inventor: Alona GOLDSTEIN, Jerusalem (IL)

(21) Appl. No.: 16/639,537

(22) PCT Filed: Aug. 14, 2018
(86) PCT No.: PCT/IL2018/050899

§ 371 Date: Feb. 14, 2020

(30) Foreign Application Priority Data
Aug. 15, 2017 (US) 62545494

(51) Int. Cl. F24S 70/30; F24S 70/20; C23C 16/455; F24S 10/70

(52) U.S. Cl. CPC F24S 70/30; F24S 10/70; C23C 16/45555; F24S 70/20

(57) ABSTRACT

A coated tube can include a metallic tube and a selective coating, coated on at least a portion of the surface of the tube. The selective coating can may include an absorbing layer and an encapsulation layer having an amorphous compound at a thickness of at most 200 nm, deposited on top of the absorbing layer. The encapsulation layer is an antireflective layer and the amorphous compound can be selected such that the antireflective layer has a refractive index greater than the refractive index of air and lower than a refractive index of the absorbing layer. The encapsulation layer can be free of defects and penetrate and seal any macro and micro-defects in the absorbing layer. The encapsulation layer can be deposited on top of the absorbing layer using atomic layer deposition (ALD) method.

### TECHNICAL FIELD OF THE INVENTION

The invention is generally related to the field of coating for solar thermal applications and more precisely to the field of protective amorphous coating for solar thermal applications.

### BACKGROUND OF THE INVENTION

A receiver for a thermo-solar power plant converts sunlight into heat using concentrated solar power (CSP). Such a receiver is constructed of a metallic (e.g., stainless steel) tube placed inside a glass tube in vacuum. The metallic tube is coated by an optically selective coating (e.g., a coating that absorbs light at visible light wavelength range and reflects back light at IR wavelength range) therefore, efficiently absorbs the sunlight with minimal heat losses.

In one approach, heat transfer fluid (HTF), for example, thermal oil or molten salts, flows through the metallic tubes to be heated by sunlight. Sunlight concentrated by mirrors is absorbed by the receiver's metallic tube and heats the HTF. The thermal energy stored in the heated HTF is used for generating steam for powering a steam turbine.

Another approach, that utilizes operation at high temperatures, is the direct steam generation (DSG) in which water is evaporated to become superheated steam directly inside the metallic tubes. The concentrated sunlight absorbed by the receiver's metallic tube heats water directly to generate superheated steam for powering the steam turbine.

Modern receivers, utilizing both HTF and DSG, operate at temperatures, as high as 550° C. and more. At such high temperatures, the selective coating undergoes degradation due to acceleration of ageing mechanisms, such as diffusion, oxidation and the like. The degradation may cause a decrease in the optical and thermal properties of the selective coating resulting in a decline in the receiver's efficiency.

In solar tower technology, receivers are commonly coated with black absorbing paints comprising a black pigment in a silicone resin, for example, Pyromark™. The black paint has a high solar absorptance. However, under the severe conditions of a solar tower, e.g., the extremely high radiation flux, the black paint coating suffers from a drastic degradation, due to peeling, cracks and corrosion that causes a significant reduction of its absorptance.

Receivers in CSP systems, such as solar trough and Fresnel, are also used for heat production in industrial applications. Non-evacuated coated tubes can be used in these applications because the convective losses are not so critical at the typically lower operating temperatures. Non-evacuated tubes enable a significant cost reduction in the materials and processing of the receiver, but require a selective coating which is stable in air.

Therefore, in order to improve the durability of the absorbing and/or selective coating for receivers in any thermo-solar power plant or for any other application, it may be beneficial to add a protective coating on top of absorbing and/or selective coating. The protective coating (e.g., layer) may limit the degradation mechanisms and improve the lifetime and durability of the selective and/or absorbing coating at high temperatures, both in vacuum and in air.

### SUMMARY OF EMBODIMENTS OF THE INVENTION

Some aspects of the invention may be related to a coated tube and a method of coating such tube. The coated tube may include a metallic tube and a selective coating, coated on at least a portion of the surface of the tube. In some embodiments, the selective coating may include an absorbing layer and an encapsulation layer comprising an amorphous compound at a thickness of at most 200 nm, deposited on top of the absorbing layer. In some embodiments, the encapsulation layer is an antireflective layer and the amorphous compound is selected such that the antireflective layer has a refractive index greater than the refractive index of air and lower than a refractive index of the absorbing layer. In some embodiments, the encapsulation layer is free of defects and configured to penetrate and seal any macro, micro and nanoscale-defects in the absorbing layer.

In some embodiments, the amorphous compound may be selected from a group consisting of amorphous: Al₂O₃, SiO₂, SiN, SiON, AlN, SiAlN, TiO₂, ATO, ITO, doped tin oxide, doped zinc oxide and a combination thereof. In some embodiments, the thickness of the encapsulation layer may be determined such that the encapsulation layer provides a destructive interference between the incident light and reflected light.

In some embodiments, the selective coating may further include an infrared (IR) reflective layer deposited between the surface of the tube and the absorbing layer. In some embodiments, the encapsulation layer is further configured to penetrate and seal defects crossing the absorbing and the reflective layers. In some embodiments, the reflective layer may be an infrared reflective layer comprising a metal selected from a group consisting of: Ag, Cu, Mo, W, Al and their alloys.

In some embodiments, the selective coating may further include an intermediate antireflective layer located between the absorbing layer and the encapsulation layer. In some embodiments, the encapsulation layer is an amorphous compound selected such that the encapsulation layer has a refractive index greater than the refractive index of air and lower than a refractive index of the absorbing layer and the thickness of the encapsulation layer together with the thickness of the intermediate antireflective layer are designed to provide a destructive interference between the incident light and reflected light. In some embodiments, the encapsulation layer is further configured to penetrate and seal defects crossing the intermediate antireflective layer, the absorbing and the IR reflective layers. In some embodiments, the metallic tube may have external diameter of at least 50 mm and a length of at least 0.5 m.

In some embodiments, the method of coating a tube may include: applying an absorbing layer on top of a metallic tube; and encapsulating the absorbing layer by applying an encapsulation layer comprising an amorphous compound, deposited on top of the absorbing layer using atomic layer deposition (ALD) method. In some embodiments, the encapsulation layer is an antireflective layer and the amorphous compound is selected such that the antireflective layer has a refractive index greater than the refractive index of air and lower than a refractive index of the absorbing layer. In some embodiments, the encapsulation layer is free of defects and configured to penetrate and seal any macro and micro-defects in the absorbing layer.

In some embodiments, the method may further include applying an intermediate antireflective layer on top of the absorbing layer prior to applying the encapsulation layer. In some embodiments, the metallic tube may have an external diameter of at least 50 mm and a length of at least 0.5 m.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIGS. 1A and 1B are illustrations of cross sections of tubes, coated with a coating according to some embodiments of the invention;

FIG. 2 is an illustration of a cross section of another tube, coated with a coating according to some embodiments of the invention;

FIG. 3 is a flowchart of a method of coating a tube according to some embodiments of the invention;

FIG. 4. is a graph of solar absorptance (alpha) measurements, as a function of exposure time at 630° C. in vacuum: comparing a sample coated with a conventional sputtered selective coating and a sample coated with a selective coating according to some embodiments of the invention;

FIGS. 5A and 5B are graphs showing optical measurements of solar absorptance (alpha) and thermal emissivity (epsilon), as a function of exposure time at 400° C. in air: comparing a sample coated with a conventional sputtered selective coating and a sample coated with a selective coating according to some embodiments of the invention;

FIG. 6 is a photograph of a sample coated with a conventional sputtered selective coating and samples coated with a selective coating according to some embodiments of the invention after exposure to 400° C. in air; and

FIG. 7 is a photograph of a sample coated with a conventional sputtered selective coating and a sample coated with a selective coating according to some embodiments of the invention following a corrosion test in a salt chamber for 24 hours.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF EMBODIMENTS OF THE PRESENT INVENTION

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

Some aspects of the invention may be directed to a protective coating for improving the lifetime and durability of a selective coating, for example, for thermo-solar receivers and method of making such coating. A tube may be made from an alloy (e.g., stainless steel, carbon steel, Inconel 625 etc.) and may be coated with a selective coating. As used herein the term “selective coating” may refer to a multilayer coating that poses several optical properties, such as the ability to absorb solar radiation at a first wavelength range while reflecting undesired radiation at a second wavelength range, for example, absorbing sunlight at the visible light range while reflecting sunlight in the IR range. A selective coating according to some embodiments of the invention may include at least an absorbing layer coating the outer surface of the tube and an antireflective (AR) layer deposited on top of the absorbing layer. In some embodiments, the selective coating may further include infrared reflecting (IRR) layer deposited on the outer surface of the tube prior to the deposition of the absorbing layer.

Some embodiments of the selective coating of the invention may include applying a final amorphous layer on top of all other layers. This final layer may have a dual purpose, providing both anti-reflectivity and encapsulation (e.g., protection) to the entire selective coating. In some embodiments, this final layer may serve only as a protective encapsulation layer. The encapsulation layer may include amorphous compounds applied using atomic layer deposition (ALD) method. Such encapsulation layer may encapsulate and protect all layers deposited prior to the deposition of the encapsulation layer. In some embodiments, the encapsulation layer may be deposited directly on top of the absorbing layer. In another embodiment, the encapsulation layer may be deposited on top of an intermediate AR layer, being deposited using other deposition techniques (e.g., sputtering), prior to the deposition of the encapsulation amorphous layer.

In some embodiments, the encapsulation amorphous layer may also be an AR layer. The anti-reflectivity properties of the encapsulation layer may be achieved by selecting a material with a refractive index (n_{AR layer}) greater than the refractive index of air and lower than the refractive index of the absorbing layer underneath (e.g., n_{AR layer} is typically between 1 to 3), and tailoring the thickness d of the encapsulation layer to provide a destructive interference between the incident light and reflected light. This condition may be fulfilled when the optical thickness dₒₚ, is a quarter-wavelength of the incident light (e.g., dₒₚ is 90-200 nm), wherein the optical thickness is defined by equation I.

dₒₚ=d*n_{AR layer} I.

When the encapsulation layer is deposited on top of an existing AR layer, the anti-reflectivity properties are achieved by a combination of both the encapsulation layer and the additional AR layer (e.g., sputtered layer). In this case, the total optical thickness is the sum of the optical thicknesses of both AR layers, as may be calculated using equation II. Therefore, the thicknesses of both the AR sputtered layer and the AR encapsulating layer may be determined according to:

d_{op_tot}=d_{amrph layer}*n_{amrph layer}+dₛₚᵤₜₜ×nₛₚᵤₜₜ II.

Wherein n_{amrph layer} is the refractive index of the amorphous encapsulation layer and the nₛₚₜₜ is the refractive index of the AR sputtered layer.

In some embodiments, the amorphous encapsulation layer may form a continuous substantially defect free layer that may further protect the entire selective coating from extreme environments at elevated temperature and rapid degradation (e.g., oxidation, diffusion, decomposition, etc.).

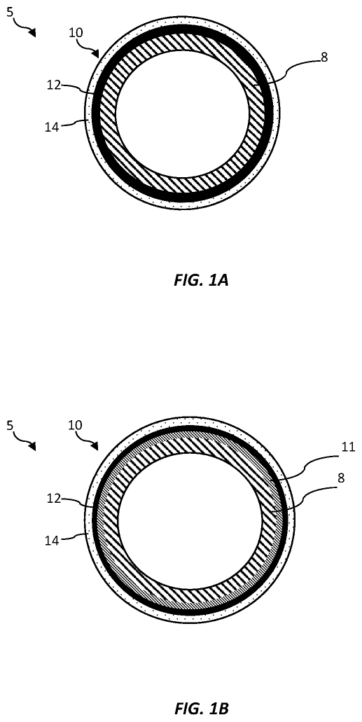

Reference is now made to FIG. 1A which is an illustration of a cross section of a tube, for example, for thermo-solar receivers, coated with amorphous compounds coating according to some embodiments of the invention. A coated tube 5 may include a metallic tube 8 coated with a selective coating 10 coated on at least a portion of the surface of tube 8. Tube 8 may include any suitable metal or alloy, for example, stainless steel, carbon steel, Inconel 625 etc. Tube 8 may have a diameter of 20-200 mm (e.g., 70 mm) and may be at least 0.5 meters long, for example, 1, 2, 3, 4 and more meters long. Selective coating 10 may include an absorbing layer 12 coating an outer surface of tube 8 and an encapsulation layer 14 encapsulating the absorbing layer 12.

The selective optical properties of coating 10 may include absorbing sunlight at the visible light range while avoiding absorbing sunlight in the IR range. Such selectivity is required in order to maximize the absorptance of solar radiation and minimize thermal losses due to black body radiation. In some embodiments, the optical properties of coating 10 may include absorbing sunlight at the visible light range.

Absorbing layer 12 may include any suitable visible light absorbing materials, for example, a multilayered structure of cermets that may include both metal and dielectrics at different ratios. For example, absorbing layer 12 may include metal inclusions such as Mo, W, Ni, Pt, etc. inside a dielectric matrix, such as Al₂O₃, AlN, SiO₂, ZrO₂, etc., deposited by sputtering, evaporation, chemical vapor deposition (CVD) or any other known method.

In some embodiments, absorbing layer 12 may include a multilayered structure of cermets, each made of two or more compounds that may be arranged in a periodic and alternating stack of a conductive layer and a dielectric layer, deposited by sputtering, evaporation, chemical vapor deposition (CVD), atomic layer deposition (ALD) or any other known method.

In some embodiments, absorbing layer 12 may include any suitable absorbing black paint material, for example, a material that includes a black pigment. The black pigment may include for example, cobalt oxide, copper manganese ferrite and the like. The black pigment may be mixed with various binders to form the black paint and may be applied to the outer surface of tube 8 using any know method. For example, the black pigment may be mixed with a silicone binder and the like. The black pigment-binder mixture may be painted, sprayed, dip coated and the like on the outer surface of tube 8. Such absorbing layer may be porous and may require better protection and encapsulation by the amorphous encapsulation layer 14.

Encapsulation layer 14 may have dual-purpose in selective coating 10, adding anti-reflectivity to coating 10 and/or protecting (e.g., by encapsulation) absorbing layer 12 from degradation. Encapsulation layer 14 may include an amorphous compound at a thickness of at most 200 nm, deposited on top of absorbing layer 12. The amorphous compound may be selected from a group consisting of: Al₂O₃, SiO₂, SiN, SiON, AlN, SiAlN, TiO₂, ATO, ITO, doped tin oxide, doped zinc oxide and a combination thereof.

In some embodiments, the amorphous compounds layer may be free of defects. As used herein, a layer free of defects, can be defined as a nanometer thick (e.g., less than 200 nm) layer with little to no micro defects and nanoscale defects, such as, pinholes, grain boundaries, vacancies and the like. An encapsulation layer 14 free of defects may encapsulate any portion of layer 12. The encapsulation may seal any macro and micro-defects such as pinholes, pores, micro-cracks and scratches formed in layer 12, thus protecting layer 12 from external influence, while maintaining the required AR properties. In such case when encapsulation layer 14 may also be an antireflective layer the amorphous compound may be selected such that encapsulation layer 14 may have a refractive index greater than the refractive index of air and lower than a refractive index of absorbing layer 12. In some embodiments, the thickness of the encapsulation layer may be determined such that the encapsulation layer may provide destructive interference between the incident light and reflected light.

Therefore, encapsulation may form much better protection from external effects, such as oxidation when the tube is exposed to air at elevated temperatures (e.g., 400° C. and the like). Furthermore, the encapsulation may also form a diffusion barrier for migration of atoms from layer 12 to the surrounding via layer 14 and/or between the sub-layers of the absorbing layer 12, via the micro-defects and nanoscale defects (e.g., pinholes and micro-cracks) across the entire thickness of the layer. These defects may provide fast diffusion paths between the layers thus accelerating degradation of each layer at high temperature. Therefore, sealing these defects by the encapsulation layer may improve durability at high temperature.

Reference is now made to FIG. 1B which is an illustration of a cross section in a tube, for example, for thermo-solar receivers, coated with amorphous compounds coating according to some embodiments of the invention. Coated tube 5 of FIG. 1B may include tube 8 and a selective coating 10. In some embodiments, selective coating 10 may include in addition to absorbing layer 12 and encapsulation layer 14, an infrared reflective (IRR) layer 11 deposited on the surface of tube 8 prior to depositing absorbing layer 12. IRR layer 11 may be deposited on the outer surface of tube 8, for example, using PVD process. IRR layer may include materials with low emissivity, such as Ag, Cu, Mo, W, Al etc and their alloys. The aim of IRR layer 11 is to reflect IR radiation from the surface of tube 8. Encapsulation layer 14 may also, penetrate, fill and seal micro-defects (e.g., pinholes and micro-cracks) across the entire thickness of the layers 11 and 12 (e.g., crossing both layers from layer 11 to layer 12) thus, may reduce the migration of atoms from layers 11 and 12 towards layer 14 via the micro-defects. The amorphous compound in layer 14 may penetrate (via the microdefects) and seal these microdefects. In some embodiments, tube 8 may include material having good IR reflectance, in such case IRR layer 11 is redundant, for example, as disclosed in FIG. 1A.

In some embodiments, the anti-reflectivity may be achieved by using two different AR layers deposited using two different deposition methods. In some embodiments, the selective coating may further include an intermediate antireflective layer deposited on top of the absorbing layer.

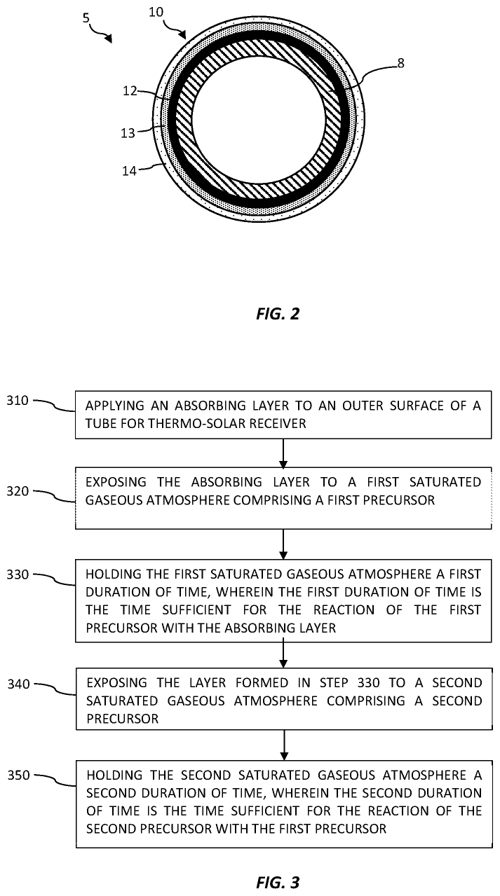

Reference is now made to FIG. 2 which is an illustration of a cut in another tube, for example, for thermo-solar receivers, coated with amorphous compounds coating according to some embodiments of the invention. Selective coating 10 may further include an intermediate AR layer 13 in addition to absorbing layer 12 and encapsulation layer 14. Intermediate AR layer 13 may include any material deposited using any method known in the art on top of absorbing layer 12. For example, intermediate AR layer 13 may include SiO₂ or Al₂O₃, SiN, SiAlOx, AlOx, etc. sputtered on top of absorbing layer 12. In some embodiments the encapsulation layer may maintain the required AR properties. In such a case, the encapsulation amorphous compound may be selected such that encapsulation layer 14 may have a refractive index greater than the refractive index of air and lower than a refractive index of absorbing layer 12 and the thickness of the encapsulation layer 14 together with the thickness of the intermediate AR layer 13 may be determined such that the sum of the layers may provide destructive interference between the incident light and reflected light. In some embodiments, amorphous encapsulation layer 14 may encapsulate any portion of intermediate antireflective layer 13.

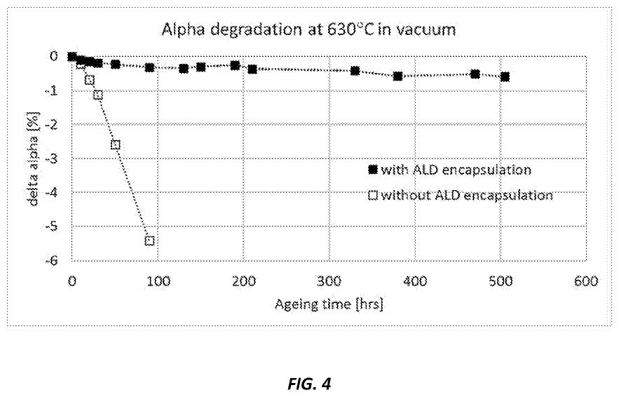

Reference is now made to FIG. 3 which is a flowchart of a method of coating a tube according to some embodiments of the invention. In step 310, an absorbing layer (e.g., layer 12) is applied on top of a metallic tube (e.g., tube 8). In some embodiments, the outer surface of the metallic tube may first be cleaned according to any method known in the art, prior to the deposition of the absorbing layer(s). In some embodiments, an IRR layer (e.g., layer 11 and/or layer 13) may be deposited, for example, using PVD or any other known method on top of the outer surface of tube 8, prior to depositing the absorbing layer.

In some embodiments, the absorbing layer may include cermets of metal and dielectric materials, applied (e.g., sputtered) on the surface of tube 8 or on top of layer 11. In some embodiments, the absorbing layer may include cermets made of sub-layers of compounds applied using for example ALD method. In some embodiments, the absorbing layer may include an absorbing paint that includes a black pigment and a binder, applied by paint brushing, airbrushing, spraying, dip coating and the like. In some embodiments, an intermediate AR layer (e.g., layer 13) may be deposited on top of absorbing layer, using for example, sputtering methods.

In some embodiments, the method may include encapsulating the absorbing layer by applying an encapsulation layer comprising an amorphous compound, deposited on top of the absorbing layer using atomic layer deposition (ALD) method. The amorphous encapsulation layer (e.g., encapsulation layer 14) may be formed as the final layer of the selective coating.

In box 320, absorbing layer 12 or antireflective layer 13 may be exposed to a first saturated gaseous atmosphere comprising a first precursor. The first saturated gaseous atmosphere may be introduced to a reactor configured to hold large longitudinal objects such as tubes. The first precursor may be selected according to the type of compound layer to be formed. A list of optional first precursors corresponding to different types of compounds is given in table 1.

In box 330, a first saturated gaseous atmosphere may be held for a first duration of time. In some embodiments, the first duration of time may be the time sufficient for a chemical reaction to occur between the first precursor and selective layer 12 or antireflective layer 13. Following the completion of the reaction the first saturated gaseous atmosphere may be evacuated from the reactor, for example, by pumping the first saturated gaseous atmosphere, flushing the reactor with inert gas, such as, N₂ and the like.

In box 340, the layer formed in boxes 320-330 may further be exposed to a second saturated gaseous atmosphere comprising a second precursor. The second saturated gaseous atmosphere may be introduced into the reactor. The second precursor may be selected according to the type of compound layer to be formed. A list of optional second precursors corresponding to different the types of compounds is given in table 1.

TABLE 1

| | Type of compound | First Precursor | Second Precursor |
|---|---|---|---|
| 1 | Al₂O₃ | trimethyl-aluminum, | H₂O |
| | | Al(CH₃)₃ | |
| 2 | SiO₂ | Silanol | Tetramethylammonium |
| | | | (TMA) |

In box 350, the second saturated gaseous atmosphere may be held inside the reactor for a second duration of time. In some embodiments, the second duration of time may be the time sufficient for a chemical reaction to occur between the second precursor and the layer formed by the first precursor. In some embodiments, following the completion of the reaction, the second saturated gaseous atmosphere may be evacuated from the reactor, for example, by pumping the second saturated gaseous atmosphere, flushing the reactor with N₂ and the like. The process disclosed in boxes 320-350 may be repeated until an amorphous compound layer in a sufficient thickness (e.g., at least 5 nm) is achieved.

In some embodiments, more than one amorphous compound may be included in layer 14. For example, alternating sub-layers of SiO₂/AlN may be included in layer 14. In some embodiments, more than two types of amorphous compounds may be included in layer 14.

### Experimental Results

Stainless steel samples (60 mm×40 mm×0.1 mm) were sputter coated with a selective coating that included an IRR layer, absorbing cermet layers and approximately 60 nm of an antireflective layer. Some of the samples were then coated using ALD, with an amorphous AR layer that included 25 nm of amorphous Al₂O₃, to form a selective coating according to some embodiments of the invention. The samples were exposed to 630° C. in vacuum and 400° C. in air for various durations. The solar absorptance (alpha) and emittance (epsilon) of each sample were measured according to ASTM G173, ASTM E903 and ASTM E408

Reference is now made to FIG. 4 which is a graph of solar absorptance (alpha) measurements as a function of exposure time at 630° C. in vacuum, of a sample coated with conventional sputtered selective coating and a sample coated with a selective coating including a protective ALD layer according to some embodiments of the invention. As can clearly be seen there is very little degradation in alpha, even after 500 hours, of the samples coated with a selective coating that included a protective ALD layer (denoted by filled squares), according to embodiments of the invention, and a sharp decline in alpha already in less than 100 hours of the unprotected sputtered samples (denoted by unfilled squares).

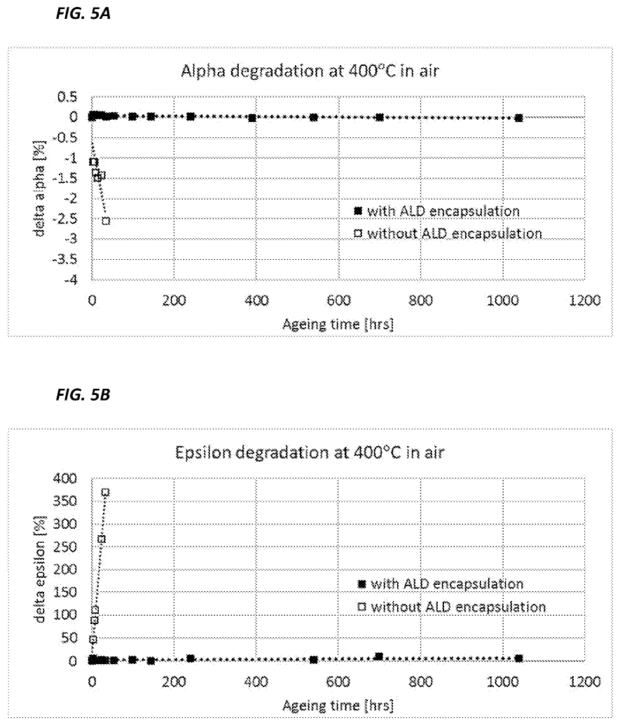

Reference is now made to FIGS. 5A and 5B which are graphs showing optical measurements of solar absorptance (alpha) and emissivity (epsilon) as a function of exposure time at 400° C. in air, of a sample coated with conventional sputtered selective coating and a sample coated with a selective coating including a protective ALD coating according to some embodiments of the invention. As can clearly be seen, alpha and epsilon were very stable even after 1000 hours, in the samples coated with a selective coating that include ALD layer (denoted in filled squares), according to embodiments of the invention. As for the samples that were not protected by ALD (denoted in unfilled squares), a clear sharp decline in alpha and a sharp incline in epsilon can be detected already after less than 100 hours, due to fast oxidation of oxide-sensitive substances in the film.

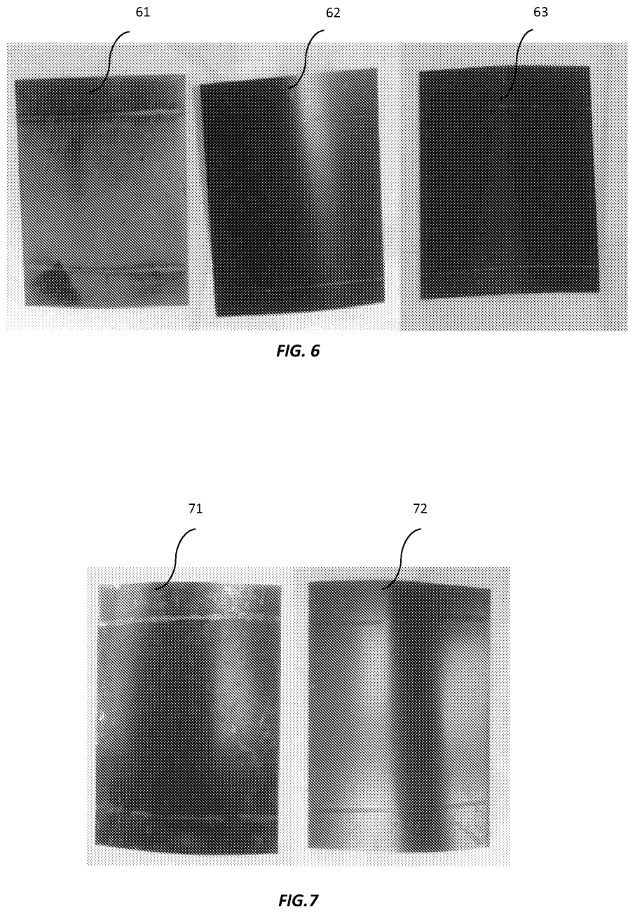

Reference is now made to FIG. 6 which is a photograph of sample 61 coated with unprotected conventional sputtered selective coating that includes an IRR layer, absorbing layer (e.g., layer 12) and a sputtered antireflective layer (e.g., layer 13) in comparison to samples 62 and 63 that were coated with a selective coating (e.g., coating 10) according to some embodiments of the invention as in FIG. 2. Samples 61 and 62 were exposed to 400° C. in air for 33 hours and sample 63 was exposed to 400° C. in air for 1040 hours. As can clearly be seen, the surface of sample 61 is rough, discolored and nonhomogeneous and the selective coating has been oxidized and/or decomposed, whereas the surface of sample 62 is smooth, shiny black and homogeneous. Even after 1040 hours, the coating on sample 63, coated with a selective coating according to embodiments of the invention, looks smooth, black and homogeneous.

Reference is now made to FIG. 7 which is a photograph of sample 71 coated with unprotected conventional sputtered selective coating and sample 72 coated with a selective coating according to some embodiments of the invention following a corrosion test in a salt chamber for 24 hours. Samples 71 and 72 were placed in a closed testing chamber, where salt water (5% NaCl) was sprayed to produce a corrosive environment of dense salt water fog at 35° C. for 24 hours, according to ASTM A 380. Sample 71 was heavily damaged by corrosion while sample 72 remained smooth, shiny and homogeneous.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

1. A coated tube, comprising:
a metallic tube; and
a selective coating, coated on at least a portion of the surface of the tube,
wherein the selective coating comprises:
an absorbing layer; and
an encapsulation layer comprising an amorphous compound at a thickness of at most 200 nm, deposited on top of the absorbing layer,
and wherein the encapsulation layer is an antireflective layer and the amorphous compound is selected such that the antireflective layer has a refractive index greater than the refractive index of air and lower than a refractive index of the absorbing layer,
and wherein the encapsulation layer is free of defects and configured to seal any macro and micro-defects in the absorbing layer.

2. The coated tube of claim 1, wherein the amorphous compound is selected from a group consisting of amorphous: Al₂O₃, SiO₂, SiN, SiON, AlN, SiAlN, TiO₂, ATO, ITO, doped tin oxide, doped zinc oxide and a combination thereof.

3. The coated tube of claim 1, wherein the thickness of the encapsulation layer is determined such that the encapsulation layer provides a destructive interference between the incident light and reflected light.

4. The coated tube of claim 1, wherein the selective coating further comprises:
an infrared reflective layer deposited between the surface of the metallic tube and the absorbing layer, and wherein the encapsulation layer is further configured to penetrate and seal defects crossing the absorbing and the infrared reflective layers.

5. The coated tube of claim 1, further comprising an intermediate antireflective layer deposited between the absorbing layer and the encapsulation layer.

6. The coated tube of claim 1, wherein the absorbing layer comprises an absorbing black paint material.

7. The coated tube of claim 1, wherein the metallic tube has external diameter of at least 20 mm and a length of at least 0.5 m.

8. A method of coating a tube, comprising:
applying an absorbing layer on top of a metallic tube; and
encapsulating the absorbing layer by applying an encapsulation layer comprising an amorphous compound, deposited on top of the absorbing layer using atomic layer deposition (ALD) method,
wherein the encapsulation layer is an antireflective layer and the amorphous compound is selected such that the antireflective layer has a refractive index greater than the refractive index of air and lower than a refractive index of the absorbing layer,
and wherein the encapsulation layer is free of defects and configured to penetrate and seal any macro and micro-defects in the absorbing layer.

9. The method of claim 8, wherein the tube has an external diameter of at least 20 mm and a length of at least 0.5 m.

10. A selective coating for tubes to be coated on at least a portion of the surface of the tube, the selective coating comprising:
an absorbing layer; and
an encapsulation layer comprising an amorphous compound at a thickness of at most 200 nm, deposited on top of the absorbing layer,
and wherein the encapsulation layer is an antireflective layer and the amorphous compound is selected such that the reflective layer has a refractive index greater than the refractive index of air and lower than a refractive index of the absorbing layer,
and wherein the encapsulation layer is free of defects and configured to seal any macro and micro-defects in the absorbing layer.

11. The selective coating of claim 10, wherein the amorphous compound is selected from a group consisting of amorphous: Al₂O₃, SiO₂, SiN, SiON, AlN, SiAlN, TiO₂, ATO, ITO, doped tin oxide, doped zinc oxide and a combination thereof.

12. The selective coating of claim 10, wherein the thickness of the encapsulation layer is determined such that the encapsulation layer provides a destructive interference between the incident light and reflected light.

13. The selective coating of claim 10, further comprising:
an IR reflective layer deposited between the surface of the metallic tube and the absorbing layer, wherein the encapsulation layer is further configured to penetrate and seal defects crossing the absorbing and the reflective layers.

14. The selective coating of claim 13, wherein the reflective layer is an infrared reflective layer comprising a metal selected from a group consisting of: Ag, Cu, Mo, W, Al and their alloys.

15. The selective coating of claim 10, further comprising an intermediate antireflective layer located between the absorbing layer and the encapsulation layer.

16. The selective coating of claim 10, wherein the absorbing layer comprises an absorbing black paint material.
